(19) United States
(12) Patent Application Publication
(10) Pub. No.: US 2008/0038584 A1
(43) Pub. Date: Feb. 14, 2008

(54) ORGANIC ELECTROLUMINESCENCE ELEMENT

(76) Inventor: Tomonori AKAI, Tokyo-to (JP)

Correspondence Address: LADAS & PARRY LLP, 224 SOUTH MICHIGAN AVENUE, SUITE 1600, CHICAGO, IL, 60604, US

(21) Appl. No.: 11/835,536

(22) Filed: Aug. 8, 2007

(30) Foreign Application Priority Data
Aug. 11, 2006 (JP) 2006-219945

(51) Int. Cl. B32B 9/00

(52) U.S. Cl. 428/691; 428/688; 428/690

(57) ABSTRACT

A main object of the present invention is to provide an organic EL element having high chromatic purity and excellent display quality. To achieve the object, the present invention provides an organic electroluminescence element comprising: a transparent substrate; a transparent or semitransparent-first electrode layer formed on the transparent substrate; an organic EL layer formed on the transparent or semitransparent-first electrode layer and containing at least a light emitting layer; a semitransparent-second electrode layer formed on the organic EL layer; a transparent or semitransparent-optical path length adjusting layer formed on the semitransparent-second electrode layer and made of an inorganic material; and a reflecting layer formed on the transparent or semitransparent-optical path length adjusting layer.

### BACKGROUND OF THE INVENTION

1. Field of the Invention

The present invention relates to an organic electroluminescence element, which utilizes optical interference.

2. Description of the Related Art

The organic electroluminescence (which may be hereinafter abbreviated as EL) element in which the light emitting layer is sandwiched between a pair of electrodes and light is emitted by applying voltage between the electrodes has advantages such as follows: high visibility due to self light emission, excellent impact resistance because it is an entirely solid element unlike a liquid crystal element, a high response speed, less susceptibility to temperature changes, and a large viewing angle. Thus, the EL element is attracting attention for applications as light emitting elements in display devices.

The organic EL element is fundamentally constructed by a laminated structure of an anode/a light emitting layer/a cathode. As the organic EL element, a bottom emission type in which light is taken out from a side of a lower electrode and a top emission type in which light is taken out from a side of an upper electrode are known.

As to the organic EL element, it is disclosed that either the upper electrode or that the lower electrode is designed as a reflecting electrode or a reflecting layer is provided between a transparent substrate and the lower electrode or on the upper electrode, so as to improve the chromatic purity or the light emitting efficiency of the emission color (See Japanese Patent Application Laid-Open (JP-A) No. 2004-127725, for example). In such an organic EL element, since multiple interference occurs between the lower electrode and the upper electrode, the chromatic purity and the light emitting efficiency of the emission color can be improved.

Further, it is disclosed that the optical distance between the lower electrode and the upper electrode is adjusted to improve the chromatic purity and the light emitting efficiency (See JP-A Nos. 2004-127725 and 2005-93329, for example). JP-A Nos. 2004-127725 and 2005-93329 disclose that the total optical path length of a hole transporting layer, a light emitting layer and an electron transporting layer, that is, the optical path length of the organic EL layer is adjusted. In general, however, the film thickness of each of the layers making up the organic EL layer is appropriately adjusted depending upon the function required for it. Therefore, it is difficult to design the film thickness of the organic EL layer under further consideration of the optical interference.

JP-A No. 2004-127725 shows bottom emission type and top emission type organic EL elements, and JP-A No. 2005-93329 shows a bottom emission type organic EL element.

In the case of the bottom emission type organic EL element, it is usual that a reflecting electrode is used as the upper electrode, and a transparent electrode such as an ITO film is used as the lower electrode. In the case of the bottom emission type organic EL element utilizing the optical interference, for example, a reflecting electrode is used as the upper electrode, and as the lower electrode is used a semitransparent reflecting electrode, which partially transmits and partially reflects the light from the light emitting layer. JP-A No. 2005-93329 shows as an example that a thin film of a metal containing such as Al, Mo, Ti, Cr, or Ag is used in a thickness of around 1 nm to 50 nm as the semitransparent reflecting electrode. However, it is difficult to select a material for the semitransparent reflecting electrode, since a metal needs to be appropriately selected, which has the same characteristics as those of ITO or the like. Further, if desired characteristics are not obtained only by the thin film of the metal, the surface of the thin metal film needs to be treated.

Further, in the case of the top emission type organic EL element, it is usual that a transparent electrode such as an ITO film or the like is used as the upper electrode, and a reflecting electrode is used as the lower electrode. In the case of the top emission type organic EL element utilizing the optical interference, for example, a reflecting electrode is used as the lower electrode, and as the upper electrode is used a semitransparent reflecting electrode which partially transmits and partially reflects the light from the light emitting layer.

Further, it is disclosed that a low-refractive index-lamination structural body is provided in the organic EL element utilizing the optical interference so as to reduce reflection of the external light (See JP-A No. 2004-152751, for example). JP-A No. 2004-152751 discloses an organic EL element having a low-refractive index-lamination structural body in which a first semitransparent film, a second semitransparent film and a reflecting layer are laminated. In the low-refractive index-lamination structural body, the thicknesses of the first semitransparent film and the second semitransparent film are adjusted to weaken the reflected light through the optical interference.

There are several embodiments as the layered structure of the organic EL element having such a low-refractive index-lamination structural body. For example, a bottom emission type organic EL element is disclosed, in which the low-refractive index-lamination structural body functions as a back face electrode structural body. In this case, the first semitransparent film may function as an electrode or the reflecting layer may function as an electrode.

Further, in the organic EL element, since the materials constituting the organic EL layer are susceptible to physical or chemical environmental changes, non-luminous point called “dark spot” may be often formed. For this reason, it is disclosed that a gas barrier layer is provided on an organic EL layer so as to prevent invasion of water or oxygen in air, which is one of causes for the dark spot generation (See JP-A No. 8-279394, for example).

The JP-A No. 2004-152751 describes nothing about the gas barrier properties at all. Further, since the second semitransparent film is made of an organic material, it cannot be said that the gas barrier properties is sufficient against moisture vapor or oxygen.

### SUMMARY OF THE INVENTION

The present invention has been accomplished in light of the above problems, and is aimed mainly at providing an organic EL element having high chromatic purity and excellent display quality.

To achieve the object, the present invention provides an organic EL element comprising: a transparent substrate; a transparent or semitransparent-first electrode layer formed on the transparent substrate; an organic EL layer formed on the transparent or semitransparent-first electrode layer and containing at least a light emitting layer; a semitransparent-second electrode layer formed on the organic EL layer; a transparent or semitransparent-optical path length adjusting layer formed on the semitransparent-second electrode layer and made of an inorganic material; and a reflecting layer formed on the transparent or semitransparent-optical path length adjusting layer.

According to the present invention, the chromatic purity can be enhanced by optical interference through appropriately setting the film thickness of the transparent or semitransparent-optical path length adjusting layer depending upon the wavelength of the emitted liquid from the light emitting layer. Therefore, since the film thickness of the organic EL layer needs not be designed to enhance the chromatic purity, freedom degree in designing the film thickness can be enlarged.

Further, according to the present invention, since the transparent or semitransparent-optical path length adjusting layer is formed on the semitransparent-second electrode layer, the semitransparent-second electrode layer and the organic EL layer can be protected from surrounding moisture and oxygen. Particularly, the transparent or semitransparent-optical path length adjusting layer made of the inorganic material has a better gas barrier property against oxygen and moisture vapor as compared with the layer made of the organic material. Therefore, for example, when the semitransparent-second electrode layer contains a metal having a relatively high reactivity, the oxidation of the metal can be prevented, and deterioration in the light emission characteristics can be suppressed. Further, it is possible to suppress the occurrence of the dark spots, etc. and enhance the display quality.

In the present invention, it is preferable that the reflecting layer has electroconductivity, and a contact area where the above semitransparent-second electrode layer and the reflecting layer contact with each other is provided in a non-display area. Since the contact area where the semitransparent-second electrode layer and the reflecting layer contact with each other is provided in the non-display area, current flows through the semitransparent-second electrode layer and also flows through the reflecting layer, so that charges can be effectively supplied to the light emitting layer and the light emitting efficiency can be enhanced.

In the present invention, it is preferable that the transparent or semitransparent-optical path length adjusting layer has a function to prevent the oxidation of the semitransparent-second electrode layer. As mentioned above, for example, when the semitransparent-second electrode layer contains the metal having relatively high reactivity, the semitransparent-second electrode layer is protected by the transparent or semitransparent-optical path length adjusting layer, so that the metal can be effectively prevented from being oxidized with moisture and oxygen.

Further, according to the present invention, the reflecting layer may be formed in pattern. By adopting such a construction, a color tone can be changed between an area where the reflecting layer is provided and an area where the reflecting layer is not provided.

Furthermore, in the present invention, it is preferable that the reflecting layer has a function to prevent the oxidation of the semitransparent-second electrode layer. Because, for example, when the semitransparent-second electrode layer contains the metal having relatively high reactivity, the semitransparent-second electrode layer can be prevented by not only the transparent or semitransparent-optical path length adjusting layer but also by the reflecting layer, so that the metal can be effectively prevented from being oxidized with the surrounding moisture and oxygen.

Further, in the present invention, it is preferable that the semitransparent-second electrode layer contains at least either one of an alkali metal or an alkaline earth metal. Although the alkali metal and the alkaline earth metal have relatively high reactivity and thus are likely to decrease the electroconductivity through oxidation, the alkali metal or the alkaline earth metal can be prevented from the oxidation even when the semitransparent-second electrode layer contains the alkali metal or the alkaline earth metal, since the transparent or semitransparent-optical path length adjusting layer is formed on the semitransparent-second electrode layer.

In the present invention, an optical path length “nd” of the transparent or semitransparent-optical path length adjusting layer preferably meets the following formula (1).

nd=λ×m/4 (1)

(in which, “n” is a refractive index of the transparent or semitransparent-optical path length adjusting layer, “d” is a film thickness of the transparent or semitransparent-optical path length adjusting layer, “λ” is a wavelength of a light to be weakened, and “m” is an arbitrary odd number.)

This is because, when the optical path length of the transparent or semitransparent-optical path length adjusting layer meets the above formula, a light having a specific wavelength can be weakened by the optical interference, so that the chromatic purity of an emission color with an intended wavelength can be enhanced.

Further, in the present invention, the inorganic material may be a wide band gap semiconductor, a metal oxide, a metal sulfide or a metal fluoride. This is because, these inorganic materials can be formed by a method which does not damage the organic EL layer.

The present invention has the following effects. That is, the chromatic purity can be enhanced by appropriately setting the thickness of the transparent or semitransparent-optical path length adjusting layer, depending upon the wavelength of the emitted light from the light emitting layer. Further, since the film thickness of the organic EL layer needs not be designed to enhance the chromatic purity, the freedom degree in designing the film thickness can be increased. In addition, since the transparent or semitransparent-optical path length adjusting layer made of the inorganic material is formed on the semitransparent-second electrode layer, the semitransparent-second electrode layer and the organic EL layer can be protected from the surrounding moisture and oxygen, and the light emission characteristics and the display quality can be improved.

### BRIEF DESCRIPTION OF THE DRAWINGS

FIG. 1 is an outlined cross sectional view showing one example of the organic EL element according to the present invention.

FIG. 2 is a figure illustrating the optical interference in the organic EL element shown in FIG. 1.

FIG. 3 is an outlined cross sectional view showing another example of the organic EL element according to the present invention.

FIG. 4 is an outlined cross sectional view showing yet another example of the organic EL element according to the present invention.

FIG. 5 is an outlined cross sectional view showing still another example of the organic EL element according to the present invention.

FIG. 6 is an outlined cross sectional view showing still another example of the organic EL element according to the present invention.

### DESCRIPTION OF THE PREFERRED EMBODIMENT

In the following, the organic EL element and the functional device according to the present invention will be explained in detail.

### A. Organic EL Element

The organic EL element of the present invention comprises: a transparent substrate; a transparent or semitransparent-first electrode layer formed on the transparent substrate; an organic EL layer formed on the transparent or semitransparent-first electrode layer and containing at least a light emitting layer; a semitransparent-second electrode layer formed on the organic EL layer; a transparent or semitransparent-optical path length adjusting layer formed on the semitransparent-second electrode layer and made of an inorganic material; and a reflecting layer formed on the transparent or semitransparent-optical path length adjusting layer.

The organic EL element according to the present invention will be explained with reference to the drawings.

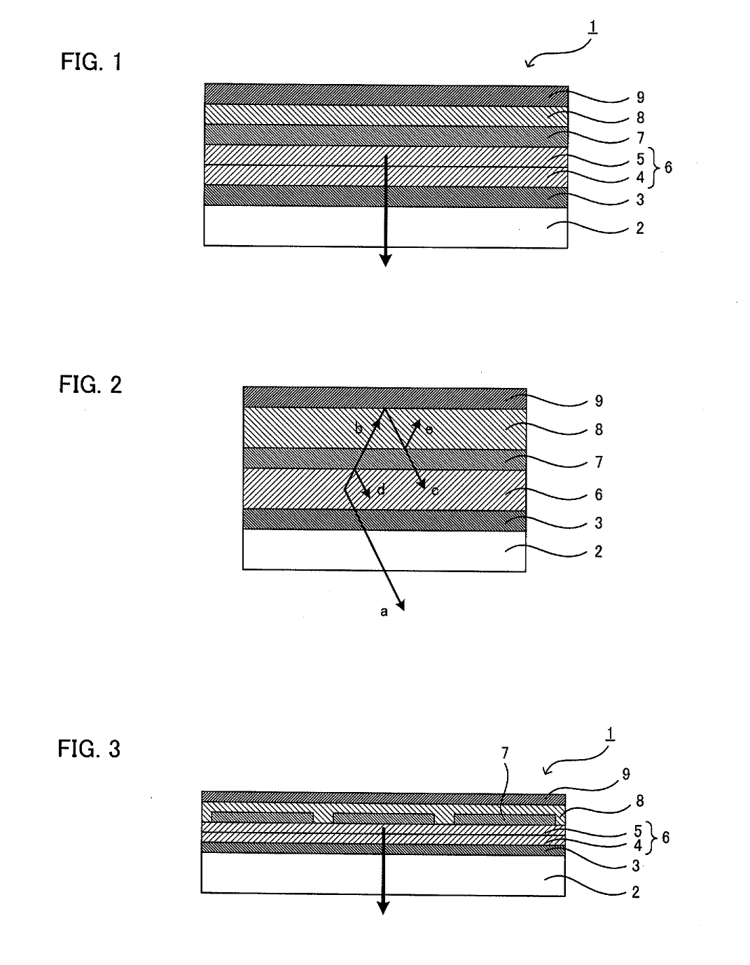

FIG. 1 is a schematically sectional view showing one embodiment of the organic EL element according to the present invention. As shown by way of example, the organic EL element 1 comprises a transparent or semitransparent-first electrode layer 3, an organic EL layer 6 composed of a hole injecting and transporting layer 4 and a light emitting layer 5, a semitransparent-second electrode layer 7, a transparent or semitransparent-optical path length adjusting layer 8 and a reflecting layer 9 which are laminated on a transparent substrate 2 in this order. This organic EL element 1 is of the bottom emission type in which light generated in the light emitting layer 5 is taken out from a side of the transparent substrate 2. The transparent or semitransparent-optical path length adjusting layer 8 is composed of an inorganic material.

Next, the optical interference in the organic EL element will be explained by using FIG. 2. In the organic EL element exemplified in FIG. 1, there are a variety of emitted rays of light. For example, as shown in FIG. 2, there are rays of light: “a”, “b”, “c”, “d”, “e”, etc. The light ray “a” is emitted from the light emitting layer 5 to a front face (the side of the transparent substrate 2). The light ray “b” is emitted from the light emitting layer 5 to a back face (a side of the transparent or semitransparent-optical path length adjusting layer 8). The light ray “c” is emitted from the light emitting layer 5 towards the back face, and reflected at an interface between the transparent or semitransparent-optical path length adjusting layer 8 and the reflecting layer 9. The light ray “d” is emitted from the light emitting layer 5 towards the back face, and reflected at an interface between the light emitting layer 5 and the second semitransparent electrode 7. The light ray hen is emitted from the light emitting layer 5 towards the back face, reflected at the interface between the transparent or semitransparent-optical path length adjusting layer 8 and the reflecting layer 9, and further reflected at an interface between the transparent or semitransparent-optical path length adjusting layer 8 and the semitransparent-second electrode layer 7. The multiple interference occurs through interference of these rays of the light.

The interference of the light depends upon the film thickness and the refractive index of each of the layers and the wavelength of the emitted light in the light emitting layer, and the light is strengthened or weakened by these light rays in combination. Further, the light emission spectrum changes depending upon this interference of the light. In the present invention, it is possible to change the light emission spectrum and improve the chromatic purity through the utilization of the optical interference by appropriately setting the film thickness of the transparent or semitransparent-optical path length adjusting layer in correspondence with the wavelength of the emitted light in the light emitting layer.

For example, when the light emitting layer emits a green light and the green light generated in the light emitting layer contains a red light around 630 nm, the chromatic purity of the green light decreases. In order to raise the chromatic purity of this green light, it is sufficient to weaken the red light around 630 nm by the interference of light.

In order to weaken a light at a wavelength λ by the interference of light, in a simple case of the organic EL element of the present invention, the optical path length of the transparent or semitransparent-optical path length adjusting layer has only to be set at about m/4 of the wavelength λ of the light desired to be weakened (“m”: an arbitrary odd number). When the refractive index and the film thickness of the transparent or semitransparent-optical path length adjusting layer are taken as “n” and “d”, respectively, the optical path length of the transparent or semitransparent-optical path length adjusting layer is given by “nd”. Therefore, in order to weaken the light of the wavelength λ by the interference of light, it is sufficient to meet the following formula (1).

nd=λ×m/4 (1)

(herein, “n” is the refractive index of the transparent or semitransparent-optical path length adjusting layer, “d” is the film thickness of the transparent or semitransparent-optical path length adjusting layer, “λ” is the wavelength, and “m” is an arbitrary odd number).

In the example of the above green light, it is sufficient to meet the following formula to weaken the red light with the wavelength of 630 nm by the interference of light.

nd=630×m/4=157.5×m

(herein, “n” is the refractive index of the transparent or semitransparent-optical path length adjusting layer, “d” is the film thickness of the transparent or semitransparent-optical path length adjusting layer, and “m” is an arbitrary odd number).

In this case, when ZnS is used for the transparent or semitransparent-optical path length adjusting layer, the refractive index “n” of ZnS is around 2.35 and thus the following formula is met.

2.35×d=157.5×m

∴d=67×m=67, 201, 335,

(herein, “d” is the film thickness of the transparent or semitransparent-optical path length adjusting layer, and “m” is an arbitrary odd number).

Therefore, the thickness “d” of the transparent or semitransparent-optical path length adjusting layer is 67 nm, 201 nm, 335 nm, . . . .

Thus, the present inventor conducted the following experiments. With respect to organic EL elements A and B, emission spectra were measured. In the organic EL element A, a glass substrate/an ITO thin film (thickness: 150 nm)/a polyethylene dioxythiophene-polystylene sulfonic acid (PEDOT-PSS) thin film (thickness: 80 nm)/a green color light emitting layer (thickness: 80 nm)/a Ca thin film (thickness: 20 nm)/a ZnS thin film (thickness: 200 nm)/an Ag thin film (thickness: 150 nm) were successively laminated. In the organic EL element B, a glass substrate/an ITO thin film (thickness: 150 nm)/a polyethylene dioxythiophene-polystylene sulfonic acid (PEDOT-PSS) thin film (thickness: 80 nm)/a green color light emitting layer (thickness: 80 nm)/a Ca thin film (thickness: 20 nm)/an Ag thin film (thickness: 150 nm) were successively laminated. In the organic EL element A, the ZnS thin film is formed as a transparent or semitransparent-optical path length adjusting layer, whereas no ZnS thin film, that is, no transparent or semitransparent-optical path length adjusting layer is formed in the organic EL element B. As determined from the above formula, the film thickness “d” of the transparent or semitransparent-optical path length adjusting layer using ZnS was set at 200 nm in the organic EL element A.

In the emission spectrum of the organic EL element A, the peak wavelength was 530 nm, and the half-band width of the spectrum was 35 nm. To the contrary, in the emission spectrum of the organic EL element B, the peak wavelength was 540 nm, and the half-band width of the spectrum was 75 nm. From the above, it was seen that when in the formula (1) was met, the half-band width of the spectrum decreased, and the chromatic purity increased.

Further, in the ideal state, the greater the film thickness “d” of the transparent or semitransparent-optical path length adjusting layer, the smaller the spectrum half-band width of the emission spectrum. For example, with respect to the film thicknesses of the transparent or semitransparent-optical path length adjusting layer being 67nm and 201 nm, the film thickness of 201 nm gave a smaller spectrum half-band width and a higher chromatic purity.

Moreover, for example, when the light emitting layer emits the green color, the chromatic purity of the green color is raised simply by strengthen the green color through the interference of light.

In order to strengthen the light of a certain wavelength A by the interference of light, in the organic EL element of the present invention, the optical path length of the transparent or semitransparent-optical path length adjusting layer is simply set at about m′/4 of the wavelength λ of the light to be strengthened (“m′”: an arbitrary even number) in an easy case. When the refractive index and the film thickness of the transparent or semitransparent-optical path length adjusting layer are taken as “n” and “d”, respectively, the optical path length of the transparent or semitransparent-optical path length adjusting layer is given by “nd”. Therefore, in order to strengthen the light of the wavelength λ by the interference of light, it is sufficient to meet the following formula (2).

nd=λ×m′/4 (2)

(herein, “n” is the refractive index of the transparent or semitransparent-optical path length adjusting layer, “d” is the film thickness of the film optical path length adjusting layer, “λ” is the wavelength, and “m′” is an arbitrary even number.

In this way, according to the present invention, the chromatic purity can be increased by appropriately setting the film thickness of the transparent or semitransparent-optical path length adjusting layer depending upon the wavelength of the light emission wavelength of the light emitting layer. Since the film thickness of the organic EL layer needs not be designed to raise the chromatic purity, the freedom degree in designing the film thicknesses can be increased.

Further, according to the present invention, since the transparent or semitransparent-optical path length adjusting layer is formed on the semitransparent-second electrode layer, the semitransparent-second electrode layer and the organic EL layer can be protected from the surrounding moisture and oxygen by the transparent or semitransparent-optical path length adjusting layer. Particularly, since the transparent or semitransparent-optical path length adjusting layer is made of the inorganic material, the gas barrier property against oxygen or moisture vapor is better as compared with a layer made of an organic material. Therefore, for example, when the semitransparent-second electrode layer contains a metal having a relatively high reactivity, the metal can be prevented from being oxidized with the surrounding moisture and oxygen. Thereby, it is possible to suppress reduction in the charge-injecting function of the semitransparent-second electrode layer and reduction in the light emission characteristics. Furthermore, it is possible to suppress the occurrence of dark spots, etc. and improve the display quality.

In addition, according to the present invention, the multiple interference is provoked through partially transmitting and partially reflecting the light from the light emitting layer by the semitransparent-second electrode layer. Therefore, unlike the conventional technique, it is no need to design the transparent or semitransparent-first electrode layer (lower electrode) as a semitransparent reflecting electrode. For this reason, it is easy to select the material for the transparent or semitransparent-first electrode layer, and a surface treatment needs not be performed to obtain desired characteristics.

In the following, each of constituent parts of the organic EL element of the present invention will be explained.

### 1. Transparent or Semitransparent-Optical Path Length Adjusting Layer

The transparent or semitransparent-optical path length adjusting layer used in the present invention is made of an inorganic material, and formed between the semitransparent-second electrode layer and the reflecting layer.

The inorganic material is used as the material for the formation of the transparent or semitransparent-optical path length adjusting layer. Such an inorganic material is not particularly limited, so long as it has transparency in a given film thickness. Meanwhile, it is preferable that the material has relatively high stability against moisture, oxygen, etc. This is because, such a transparent or semitransparent-optical path length adjusting layer can effectively protect the semitransparent-second electrode layer and the organic EL layer from moisture, oxygen, etc. That is, the transparent or semitransparent-optical path length adjusting layer preferably has a function to prevent the oxidation of the semitransparent-second electrode layer.

Further, the inorganic material to be used for the transparent or semitransparent-optical path length adjusting layer is preferably a material which can be film formed by a method not damaging the organic EL layer. It is because, this can prevent deterioration in the light emission characteristics, which would be caused when the organic EL layer undergoes a damage during the formation of the transparent or semitransparent-optical path length adjusting layer.

Further, the inorganic material to be used for the transparent or semitransparent-optical path length adjusting layer may have electroconductivity or insulation properties.

As such an inorganic material, mention may be made of wide band gap semiconductors such as compounds composed of elements in Periodic Table Groups II and VI, including ZnSe, ZnS, ZnSₓSe₁₋ₓ, etc.; metal oxides such as SiO; metal sulfides; metal fluorides, etc.

When a semitransparent-second electrode layer 7 is formed in pattern as shown in FIG. 3, a transparent or semitransparent-optical path length adjusting layer 8 is formed preferably to cover edges of the patterns of the semitransparent-second electrode layer 7. For example, when the semitransparent-second electrode layer contains a metal having a relatively high reactivity, oxidation of the metal is likely to proceed from the edges of the patterns of the semitransparent-second electrode layer. To the contrary, when the transparent or semitransparent-optical path length adjusting layer is formed to cover the edges of the patterns of the semitransparent-second electrode layer, the metal can be prevented from being oxidized from the edges of the patterns of this semitransparent-second electrode layer.

Further, the inorganic material to be used for the transparent or semitransparent-optical path length adjusting layer preferably has insulation properties. Thereby, the electric conduction between the adjacent patterns of the second semitransparent electrode can be prevented and, the occurrence of crosstalk therebetween can be suppressed.

Furthermore, the average transmittance of the transparent or semitransparent-optical path length adjusting layer in the visible light region (380 nm-780 nm) is preferably not less than 10%, and more preferably not less than 40%. In order to raise the chromatic purity by utilizing the optical interference through appropriately setting the film thickness of the transparent or semitransparent-optical path length adjusting layer, the light emitted from the light emitting layer needs to pass the transparent or semitransparent-optical path length adjusting layer 8 as shown by example in FIG. 2.

The above average transmittance is a value measured at room temperature in air by using an ultraviolet-visible spectrophotometer (UV-2200A manufactured by Shimadzu Corporation).

The thickness of the transparent or semitransparent-optical path length adjusting layer is not particularly limited, so long as a desired chromatic purity can be obtained. The thickness can be appropriately set depending upon, such as the refractive index of the inorganic material used for the transparent or semitransparent-optical path length adjusting layer, or the emission wavelength of the light emitting layer. One example of how to determine the thickness of the transparent or semitransparent-optical path length adjusting layer is as mentioned above.

Specifically, the thickness of the transparent or semitransparent-optical path length adjusting layer is preferably in a range of 1 nm to 2000 nm, more preferably in a range of 20 nm to 1000 nm, and further preferably in a range of 50 nm to 500 nm. If the thickness of the transparent or semitransparent-optical path length adjusting layer is smaller than the above range, it may be difficult to protect the semitransparent-second electrode layer and the organic EL layer from moisture, oxygen, etc. In addition, if the thickness of the transparent or semitransparent-optical path length adjusting layer is larger than the above range, it may be that the transmittance decreases or the time period for the formation of the film is prolonged.

The formation process for the transparent or semitransparent-optical path length adjusting layer is not particularly limited, so long as the method does not damage the organic EL layer. For example, the chemical vapor deposition method, the physical vapor phase growth deposition method such as vacuum deposition method, sputtering method, and ion plating method are recited. Among them, the chemical vapor deposition method and the vacuum deposition method are preferred. This is because, the kinetic energy of a gasified material is low in the chemical vapor deposition method and the vacuum deposition method so that the energy given to the organic EL layer is small.

Moreover, a coating method can be used as the formation process for the transparent or semitransparent-optical path length adjusting layer. When the transparent or semitransparent-optical path length adjusting layer is formed in a filmy fashion, it can be laminated or transferred on the semitransparent-second electrode layer directly or via an adhesive.

Especially, the vacuum deposition method is suitable as the formation process for the transparent or semitransparent-optical path length adjusting layer. This is because, the vacuum deposition method has not only the above-mentioned advantage, but also a reactive gas, such as oxygen, is not introduced therein. For this reason, even if the semitransparent-second electrode layer contains a highly reactive metal, the oxidation of this metal can be avoided.

Therefore, it is a preferable that an unreactive gas such as a rare gas is introduced in the use of the chemical vapor deposition method, the sputtering method and the ion plating method, without the introduction of the reactive gas such as oxygen gas.

As the vacuum deposition method, a resistance heating vapor deposition method, a flash vapor deposition method, an arc vapor deposition method, a laser vapor deposition method, a high-frequency heating vapor deposition method, and an electron beam vapor deposition method can be recited as examples.

### 2. Semitransparent-Second Electrode Layer

The semitransparent-second electrode layer used in the present invention is formed between the organic EL layer and the transparent or semitransparent-optical path length adjusting layer. Further, as exemplified in FIG. 2, the semitransparent-second electrode layer 7 partially transmits and partially reflects the emitted light from the light emitting layer.

The semitransparent electrode layer may be either an anode layer or a cathode layer, but is usually the cathode layer. This is because, generally the organic EL element can be more stably produced by making the lamination from the side of the anode.

The semitransparent-second electrode layer is not particularly limited, so long as it has transparency and electroconductivity at a predetermined layer thickness. However, the semitransparent-second electrode layer preferably contains a highly reactive metal. In particular, it preferably contains at least either of an alkali metal or an alkaline earth metal. Especially, the semitransparent-second electrode layer contains an alkali metal alone, an alkaline earth metal alone, an oxide of the alkali metal, an oxide of the alkaline earth metal, a fluoride of the alkali metal, a fluoride of the alkaline earth metal, or an organic complex of the alkali metal.

The reasons are as follows. The alkali metal and the alkaline earth metal are oxidized easily, and the electron injecting function of the semitransparent-second electrode layer might be lost by the oxidization of the metals. However, since the transparent or semitransparent-optical path length adjusting layer is formed on the semitransparent-second electrode layer, even if the semitransparent-second electrode layer contains the alkali metal or the alkaline earth metal, the semitransparent-second electrode layer is protected by the transparent or semitransparent-optical path length adjusting layer, and the alkali metal and the alkaline earth metal can be prevented from being oxidized with ambient moisture and oxygen.

As the alkali metal itself or the alkaline earth metal itself, Li, Cs, Mg, Ca, Sr, and Ba are recited, for example. As the oxide of the alkali metal and the oxide of the alkaline earth metal, magnesium oxide, strontium oxide, and lithium oxide are recited, for example. As the fluoride of the alkali metal and the fluoride of the alkaline earth metal, lithium fluoride, magnesium fluoride, strontium fluoride, calcium fluoride, barium fluoride, and the cesium fluoride are recited, for example. As the organic complex of the alkali metal, polymethyl methacrylate sodium polystyrenesulfonate is recited, for example.

The semitransparent-second electrode layer may be a single layer, or a laminate of plural layers.

As the semitransparent-second electrode layer in the form of a single layer, a single film of an alkali metal alone or an alkaline earth metal alone, such as Ca, Mg or Ba as well as a single film of an alloy, such as MgAg, between an alkali metal or an alkaline earth metal and a metal having high stability is recited. As to a Ca film functioning as an electrode, see Japanese Patent No. 3478824 and Appl. Phys. Lett., Vol.58, No.18, 1982-1984 (1991).

Moreover, as the semitransparent-second electrode layer made of the laminate of the plural layers, recitation may be made, for example, of a laminate made of an alkali metal or an alkaline earth metal and a metal having relatively-high stability; a laminate made of a fluoride of an alkali metal or an alkaline earth metal, an oxide of an alkali metal or an alkaline earth metal or an organic complex of an alkali metal, and a metal having relatively high stability; a laminate made of a fluoride of an alkali metal or an alkaline earth metal, an oxide of an alkali metal or an alkaline earth metal or an organic complex of an alkali metal, and an alkali metal or an alkaline earth metal; a laminate made of a fluoride of an alkali metal or an alkaline earth metal, an oxide of an alkali metal or an alkaline earth metal or an organic complexes of an alkali metal, an alkali metal or an alkaline earth metal, and a metal having relatively high stability. Specifically, Ca/Ag, LiF/Al, LiF/Ca, and LiF/Ca/Ag are recited as examples.

Among the above-mentioned materials, the semitransparent-second electrode layer is preferably: the single film made of the alkali metal alone; or the alkaline earth metal alone; or the laminate made of the fluoride of the alkali metal or the alkaline earth metal, the oxide of the alkali metal or the alkaline earth metal or the organic complex of the alkali metal, and the alkali metal or the alkaline earth metal. Especially, the semitransparent-second electrode layer is preferably the single film made of Ca or the laminate of LiF/Ca. This is because they are susceptible to oxidization, but have relatively high electroconductivity and high transparency.

When a relatively highly reactive metal such as an alkali metal or an alkaline earth metal is used for the semitransparent-second electrode layer, the electron injecting properties to the light emitting layer can be improved. However, since the reactivity of the alkali metal or the alkaline earth metal is relatively high as mentioned above, the electroconductivity is readily decreased through oxidation. To prevent the alkali metal and the alkaline earth metal from being oxidized, it was a common practice that a film of a metal having relatively-high stability, such as Ag or Al, was deposited on a film of an alkali metal or an alkaline earth metal or a compound thereof, or a film of an alloy between an alkali metal or an alkaline earth metal and a metal having high stability, such as Ag and Al, was used. However, the transparency of the film might decrease, if the content of the metal having relatively-high stability in the film is increased. In the present invention, since the transparent or semitransparent-optical path length adjusting layer can prevent the oxidation of the alkali metal and the alkaline earth metal contained in the semitransparent-second electrode layer, when the semitransparent-second electrode layer contains the metal with high stability, the content of that metal with relatively-high stability, that is, the content of the metal that decreases the transparency can be reduced.

The average transmittance in the visible light region (380 nm to 780 nm) of the semitransparent-second electrode layer is preferably not less than 10%, and more preferably not less than 50%. This is because, in order to increase the chromatic purity by utilizing the optical interference through appropriately setting the film thickness of the transparent or semitransparent-optical path length adjusting layer, it is necessary that the emitted light from the light emitting layer partially passes and partially reflects the semitransparent-second electrode layer 7. A method for measuring the average transmittance is the same as the method described in the item of the transparent or semitransparent-optical path length adjusting layer.

The thickness of the semitransparent-second electrode layer is not particularly limited, and is appropriately set depending upon the material to be used. Specifically, the thickness of the semitransparent-second electrode layer is preferably in a range of 0.2 nm to 100 nm, more preferably in a range of 0.2 nm to 50 nm. The reason is as follows. If the thickness of the semitransparent-second electrode layer is too small, resistance might become higher. On the other hand, if the thickness too large, the transmittance might become lower.

The formation process for the semitransparent-second electrode layer is not particularly limited, so long as it does not damage the organic EL layer. The formation process for the semitransparent-second electrode layer is the same as the formation process of the transparent or semitransparent-optical path length adjusting layer mentioned above, explanation is omitted herein.

### 3. Reflecting Layer

The reflecting layer used in the present invention is formed on the transparent or semitransparent-optical path length adjusting layer. As exemplified in FIG. 2, the reflecting layer 9 reflects the emitted light from the light emitting layer.

The material for forming the reflecting layer is not particularly limited, so long as it has reflecting properties. However, it is preferable that the material having relatively high stability against moisture, oxygen or the like. Such a reflecting layer can protect the semitransparent-second electrode layer and the organic EL layer against such as moisture or oxygen. That is, the reflecting layer preferably has a function to prevent the oxidation of the semitransparent-second electrode layer.

The material to form the reflecting layer is preferably a material which can be film formed by a method that does not damage the organic EL layer. This is because, it can prevent the reduction in the light emission characteristics, which would be caused when the organic EL layer receives a damage during the formation of the reflecting layer.

As such a forming material of the reflecting layer, Al, Au, Cr, Cu, Ag, etc. can be recited.

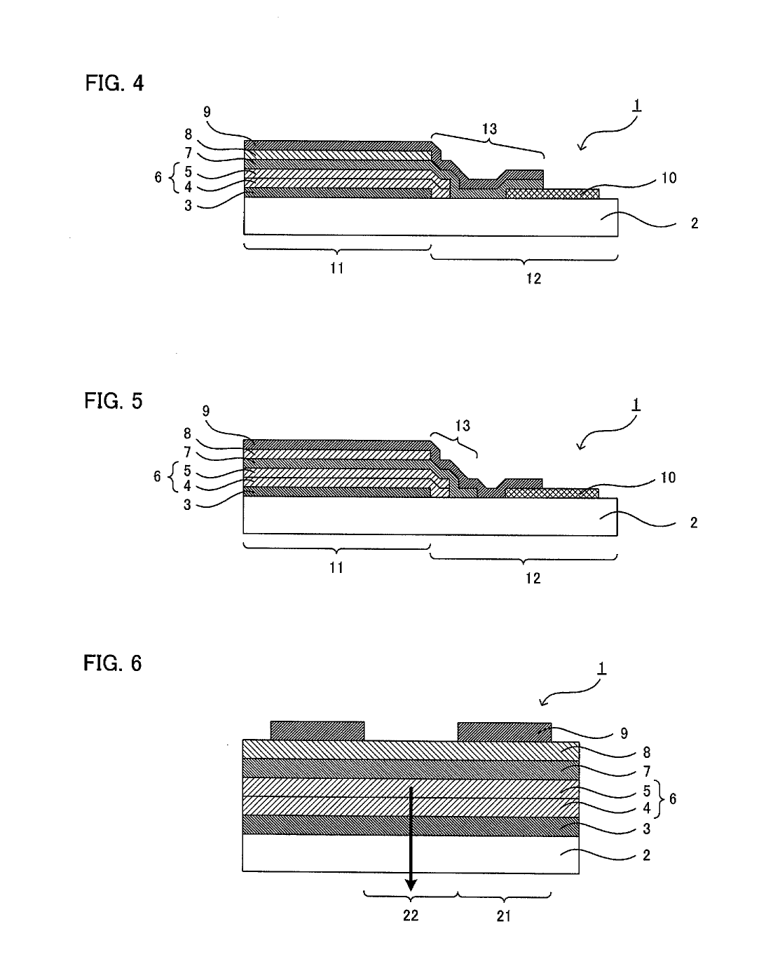

The reflecting layer may have electroconductivity. In this case, the electroconductivity of the reflecting layer is preferably higher than that of the semitransparent-second electrode layer. Specifically, a value obtained by dividing the resistivity of the reflecting layer by its film thickness is preferably not more than a value obtained by dividing the resistivity of the semitransparent-second electrode layer by its film thickness. In this case, as shown by an example in FIG. 4, a contact area 13 where the semitransparent-second electrode layer 7 and the reflecting layer 9 contact with each other is provided in a non-display area 12.

In organic EL element 1 illustrated in FIG. 4, when voltage is applied to the transparent or semitransparent-first electrode layer 3 and the semitransparent-second electrode layer 7, current flows into the organic EL layer 6 from the take-out electrode 10 through the semitransparent-second electrode layer 7, and the semitransparent-second electrode layer 7 functions as an electroconductive passage. At this time, since the semitransparent-second electrode layer 7 and the reflecting layer 9 contact with each other in the contact area 13 of the non-display area 12, the reflecting layer 9 assists the electroconductivity of the semitransparent-second electrode layer 7. Accordingly, current also flows through the reflecting layer 9, and it functions also as an electroconductive passage. That is, the reflecting layer provided in the non-display area functions as a bus electrode for the semitransparent-second electrode layer, so that the electron conductibility of charge is improved. Thus, charge can be efficiently supplied to the light emitting layer.

Further, in the organic EL element 1 illustrated in FIG. 4, when the take-out electrode 10 is made of an electroconductive inorganic oxide such as ITO, the metal contained in the semitransparent-second electrode layer may be oxidized through a reaction with oxygen contained in the take-out electrode in the area where the semitransparent-second electrode layer 7 contacts the take-out electrode 10. In this case, there is a risk that the electroconductivity of the semitransparent-second electrode layer might decrease in the area where the semitransparent-second electrode layer and the take-out electrode contact with each other. However, since the contact area 13 in which the semitransparent-second electrode layer 7 and reflecting layer 9 contact with each other is provided in the non-display area 12, the reflecting layer can supplement reduction in the electroconductivity of the semitransparent-second electrode layer, even if the electroconductivity of the semitransparent-second electrode layer is partially decreased by the influence of the oxygen contained in the take-out electrode.

When the resistance of the reflecting layer is smaller than that of the semitransparent-second electrode layer in the non-display area, the take-out electrode, the semitransparent-second electrode layer and reflecting layer form an electroconductive passage. For instance, in organic EL element 1 shown in FIG. 4, current flows from the take-out electrode 10 to the semitransparent-second electrode layer 7 and the reflecting layer 9, and further to the semitransparent-second electrode layer 7, thereby supplying electrons to the light emitting layer 5. Moreover, for instance, in the organic EL element 1 shown in FIG. 5, current flows from the take-out electrode 10 to the reflecting layer 9, and further to the semitransparent-second electrode layer 7, thereby supplying current to the light emitting layer 5. Thus, the reflecting layer provided in the non-display area functions as a bus electrode of the semitransparent-second electrode layer so that the electron conductibility of charge can be improved to effectively supply charge to the light emitting layer.

Among the above mentioned materials for forming the reflecting layer, Ag and Al are preferably used as having relatively high electroconductivity.

As exemplified in FIG. 1, the reflecting layer 9 may be formed on the entire surface of the transparent or semitransparent-optical path length adjusting layer 8, or as shown by an example in FIG. 6, the reflecting layer 9 may be formed in pattern on the transparent or semitransparent-optical path length adjusting layer 8.

As exemplified in FIG. 6, when the reflecting layer 9 is formed in pattern, the emitted light from the light emitting layer is reflected at the interface between the transparent or semitransparent-optical path length adjusting layer 8 and the reflecting layer 9 in a reflecting area 21 provided with the reflecting layer 9. In a transmitting area 22 where no reflecting layer 9 is provided, the emitted light from the light emitting layer passes directly the transparent or semitransparent-optical path length adjusting layer 8. Owing to this, the color tone of the emitted light can be changed between the reflecting area 21 and the transmitting area 22. For example, when the light emitting layer emits a blue light and the blue light emitted from the light emitting layer contains a green light, the color tone can be varied such that the blue color and the blue green color are in the reflecting area and the transmitting area, respectively.

The average refractive index of the reflecting layer in the visible light region (380 nm to 780 nm) is preferably not less than 10%, and more preferably not less than 30%. If the refractive index is in the above range, the emitted light from the light emitting layer can be effectively reflected at the interface between the transparent or semitransparent-optical path length adjusting layer 8 and the reflecting layer 9 as exemplified in FIG. 2.

The refractive index is a value measured at room temperature in air by using the ultraviolet-visible light spectrophotometer (UV-2200A manufactured by Shimadzu Corporation), while taking air as a reference. The average refractive index is a value by averaging refractive index values in the visible light range (380 nm to 780 nm).

The thickness of the reflecting layer is not particularly limited, and is appropriately set depending upon the material used. Specifically, the thickness of the reflecting layer is preferably in a range of 10 nm to 1000 nm. If the thickness of the reflecting layer is too small, the refractive index may be lower or the resistance may be higher, whereas if the thickness of the reflecting layer is too large, the time period for forming the film may be longer.

The formation process for the reflecting layer is not particularly limited, so long as it does not damage the organic EL layer. The formation process for the reflecting layer is the same as the formation method of the transparent or semitransparent-optical path length adjusting layer mentioned above, explanation is omitted herein.

### 4. Organic EL layer

The organic EL layer used in the present invention is composed of one or more organic layers including at least the light emitting layer. In other words, the organic EL layer is the layer which includes at least the light emitting layer and is composed of one or more organic layers. When the organic EL layer is formed by the coating method, it is usually composed of one or two organic layers, since it is difficult to laminate a lot of layers in connection with the solvent. However, it can be composed of an increased number of layers by appropriately selecting organic materials having respectively different solubilities to the solvent or by using the vacuum deposition method in combination.

As an organic layer formed in the organic EL layer besides the light emitting layer, the hole injecting layer, the hole transporting layer, the electron injecting layer and the electron transporting layer can be recited. The hole transporting layer, which is to impart the hole transporting function to the hole injecting layer, may be often integrated with the hole injecting layer. Further, the electron transporting layer, which is to impart the electron transporting function to the electron injecting layer, may be integrated with the electron injecting layer.

In addition, as the organic layer formed inside the organic EL layer, recitation is made, for example, of a layer, such as a carrier block layer, in which excitons are confined inside the light emitting layer by preventing passage of holes or electrons and further preventing diffusion of the excitons, so that recombination efficiency is improved.

As mentioned, the organic EL layer often has the laminated structure in which various layers are laminated, and there are many kinds of such a laminated structure. For instance, the laminated structure like a hole injecting and transporting layer/a light emitting layer is preferred.

Hereinafter, each of components of the organic EL layer will be described.

### (1) Light Emitting Layer

The light emitting layer used in the present invention has the function that provides a field where electrons and holes are recombined to emit light.

The light emitting layer may be: a layer for emitting a monochromatic color light of such as a blue, green, yellow, orange or red color ; a layer for emitting a white color light which is obtained by mixing plural colors; or a layer in which light emitting patterns of three primary colors are arranged.

The white emission light can be obtained by superimposing emitted lights from plural light emitting bodies. For example, the light emitting layer which emits the white color light may be: one that obtains the white color emission light by superimposing two emission color lights of predetermined peak wavelengths from two kinds of light emitting bodies, or one that obtains the white emission color light by superimposing three emission color lights of predetermined peak wavelengths from three kinds of light emitting bodies.

When the light emitting layer is to emit a monochromatic color light, the chromatic purity of the intended monochromatic color can be increased by appropriately setting the film thickness of the transparent or semitransparent-optical path length adjusting layer depending upon the light emission wavelength.

Further, when the light emitting layer is to emit the white color light and when the light emitting patterns of the three primary colors are arranged, the balance among the three primary colors can be improved by appropriately setting the film thickness of the semitransparent film thick-adjusting layer depending upon the wavelength of the emitted light.

As a material for forming the light emitting layer, a pigment based light emitting material, a metal complex based light emitting material or a polymer based light emitting material is usually used.

As the pigment based light emitting material, for example, cyclopentadiene derivatives, tetraphenyl butadiene derivatives, triphenyl amine derivatives, oxadiazol derivatives, pyrazoloquinoline derivatives, distylyl benzene derivatives, distylyl arylene derivatives, silol derivatives, a thiophene ring compound, a pyridine ring compound, perynon derivatives, perylene derivatives, oligothiophene derivatives, triphmanyl amine derivatives, coumalin derivatives, oxadiazol dimer, or pyrazoline dimer can be presented.

Moreover, as the metal complex based light emitting material, for example, metal complexes having Al, Zn, Be, Ir or Pt, or a rare earth metal such as Tb, Eu or Dy as the central metal, and oxadiazol, thiadiazol, phenyl pyridine, phenyl benzoimidazol, a quinoline structure, or the like as the ligand can be cited. As examples of the metal complex, aluminum quinolinol complex, benzoquinolinol beryllium complex, benzoxazol zinc complex, benzothiazol zinc complex, azomethyl zinc complex, porphiline zinc complex, europium complex, or iridium metal complex, or platinum metal complex can be cited. Specifically, tris(8-quinolinolato)aluminum complex (Alq₃) can be presented.

As the polymer based light emitting material, recitation can be made of, for example, polyparaphenylene vinylene derivatives, polythiophene derivatives, polyparaphenylene derivatives, polysilane derivatives, polyacetylene derivatives, polyvinylcarbazole, polyfluorenone derivatives, polyfluorene derivatives, polyquinoxaline derivatives, polydialkylfluorene derivatives, and copolymers of any of them. Further, polymers of the above-mentioned pigment based light emitting materials and the above-mentioned metal complex based light emitting materials are also recited.

Moreover, a dopant that performs fluorescent emission or phosphorescent emission may be incorporated into the light emitting layer so as to improve the light emitting efficiency and change the light emission wavelength, for example. As such a dopant, for example, perylene derivatives, coumarin derivatives, rubrene derivatives, quinacridone derivatives, squalium derivatives, porphiline derivatives, styryl pigments, tetracene derivatives, pyrazoline derivatives, decacyclene, phenoxazone, quinoxaline derivatives, carbazol derivatives, and fluolene derivatives can be presented.

The thickness of the light emitting layer is not particularly limited as long as it is a thickness capable of providing the field for recombination of electrons and holes so as to provide the light emitting function. For example, it can be about 1 nm to 200 nm.

The method for forming the light emitting layer is not particularly limited, so long as it enables the formation of a micropattern required by the organic EL element. As the formation method for the light emitting layer, recitation can be made, for example, of the vapor deposition method, a printing method, an ink jet method, a spin coating method, a casting method, a dipping method, a bar coating method, a blade coating method, a roll coating method, a gravure coating method, a flexographic printing method, a spray coating method, and a self-assembly method (an alternate adsorption method and a self-assembled monomolecular filming method). Among them, the vapor deposition method, the spin coating method, and the inkjet method are preferred.

When a display device of a full color display type or a multicolor display type is produced by using the organic EL element, it is necessary to form respectively a minute shape of each of the light emitting layers emitting different color and arrange them in a given arrangement. Thus, the light emitting layers need to be patterned sometimes. As a method for patterning the light emitting layers, recitation is made of a method in which each of the different light emitting colors is coated or vapor deposited through masking or a method in which each of the different light emitting colors is patterned by printing or ink jetting. Furthermore, the light emitting layers may be patterned through forming partitions among the arranged light emitting layers. The method of forming the partitions has an advantage that the light emitting material is not spread over an adjacent area through wetting, when the light emitting layer is formed with the inkjet method or the like.

As the material for forming such partitions, photosetting type resins such as a photosensitive polyimide resin and an acrylic resin, a thermosetting type resin, an inorganic material may be used, for example. In addition, a treatment by which the surface energy (wettability) of the partition forming material is changed may be performed.

### (2) Hole Injecting and Transporting Layer

In the present invention, the hole injecting and transporting layer may be formed between the light emitting layer and the anode layer. As shown in FIG.1 for example, when the transparent or semitransparent-first electrode layer 3 is an anode, a hole injecting and transporting layer 4 is formed between the transparent or semitransparent-first electrode layer 3 and a light emitting layer 5.

The hole injecting and transporting layer is not particularly limited, so long as the holes injected from the anode can be transported into the light emitting layer. The hole injecting and transporting layer may be one consisting of either a hole injection layer or a hole transporting layer, or may be one consisting of both the hole injection layer and the hole transporting layer. The hole injecting and transporting layer may be a single layer that has both of the hole injecting function and the hole transporting function.

The material used for the hole injecting and transporting layer is not particularly limited as long as it is a material capable of stably transporting holes injected from the anode into the light emitting layer. As examples of the material used for the hole injecting and transporting layer, a phenyl amine based one, a star burst type amine based one, a phthalocyanine based one; oxides such as vanadium oxide, molybdenum oxide, ruthenium oxide, and aluminum oxide; amorphous carbon; or polyaniline, polythiophene, polyphenylene vinylene and derivatives thereof can be used. As a specific example, bis(N-(1-naphthyl-N-phenyl) benzidine (α-NPD), 4,4,4-tris(3-methyl phenyl phenyl amino) triphenyl amine (MTDATA), poly(3,4-ethylene dioxythiophene)-polystyrene sulfonic acid (PEDOT-PSS), and polyvinyl carbazole (PVCZ) can be presented.

Moreover, the thickness of the hole injecting and transporting layer is not particularly limited as long as it is a thickness capable of sufficiently performing the function of injecting holes from the anode and transporting the holes to the light emitting layer. Specifically, it is in a range of 0.5 nm to 300 nm, in particular it is preferably in a range of 10 nm to 100 nm.

### (3) Electron Injecting Layer

In the present invention, the electron injecting layer may be formed between the light emitting layer and the cathode. When the semitransparent-second electrode layer is a cathode for example, an electron injecting layer is formed between the light emitting layer and the semitransparent-second electrode layer.

The material for forming the electron injecting layer is not particularly limited, so long as the material can stabilize the injection of electrons into the light emitting layer. As the formation material of the electron injecting layer, recitation may be made, for example, of metals themselves such as alkali metals or alkaline earth metals, including strontium, calcium, lithium, and cesium; oxides of alkali metals or alkaline earth metals such as magnesium oxide, strontium oxide, and lithium oxide; fluorides of alkali metals or alkaline earth metals such as lithium fluoride, magnesium fluoride, strontium fluoride, calcium fluoride, barium fluorides, and cesium fluorides; and organic complexes of alkali metals such as polymethylmethacrylate sodium polystyrenesulfonate.

Among them, the fluorides of the alkaline earth metals are preferred since they can stabilize the organic EL layer and prolong the life thereof. This is because the reactivity of the fluorides of the alkaline earth metals with water is lower than that of the compounds of the alkali metals and the oxides of the alkaline earth metals mentioned above, and because the water absorption of the electron injecting layer during and after the formation of the electron injecting layer is smaller in the former than in the latter. This is also because the fluorides of the alkaline earth metals have higher melting points and better heat resistance and stability as compared with the compounds of the alkali metals mentioned above.

Furthermore, as mentioned, the alkali metals and the alkaline earth metals are oxidized easily, so that the electron injecting function of the electron injecting layer might be lost by the oxidation of the metals. Whereas in the present invention, since the transparent or semitransparent-optical path length adjusting layer is formed, even if the electron injecting layer contains the alkali metal or the alkaline earth metal, the electron injecting layer is protected by the transparent or semitransparent-optical path length adjusting layer, so that the metal can be prevented from being oxidized with ambient moisture and oxygen.

The thickness of the electron injecting layer is preferably around 0.2 nm to 10 nm, considering the conductivity and the transmittance of the compounds of the alkali metals and the alkaline earth metals mentioned above.

### (4) Electron Transporting Layer

In the present invention, the electron transporting layer may be formed between the light emitting layer and the cathode. For example, when the semitransparent-second electrode layer is a cathode, an electron transporting layer is formed between the light emitting layer and the semitransparent-second electrode layer. Further, when the electron injecting layer is formed, the layers are formed in the order of the light emitting layer, the electron transporting layer, the electron injecting layer, and the semitransparent-second electrode layer.

The material for forming the electron transporting layer is not particularly limited, so long as the material can transport electrons injected from the cathode or the electron injecting layer into the light emitting layer. As the material for forming the electron transporting layer, recitation may be made, for example, of phenanthroline derivatives such as bathocuproin (BCP) and bathophenanthroline (Bpehn) and aluminium quinoline derivatives such as tris (8-quinolinolato) aluminum complex (Alq3).

### 5. Transparent or Semitransparent-First Electrode Layer

The transparent or semitransparent-first electrode layer used in the present invention may be an anode or a cathode, but it is usually the anode. This is because, the organic EL element can be produced generally more stably by making the lamination from the side of the anode.

Since the organic EL element according to the present invention is of the bottom emission type in which light is taken out from the side of the transparent or semitransparent-first electrode layer, the transparent or semitransparent-first electrode layer needs to have transparency. The average transmittance of the transparent or semitransparent-first electrode layer in the visible light region (380 nm to 780 nm) is preferably not less than 10%, and more preferably not less than 50%.

The material for forming the transparent or semitransparent-first electrode layer is not particularly limited, so long as it is a transparent electroconductive material. For instance, electroconductive inorganic oxides such as In—Sn—O(ITO), In—Zn—O (IZO), In—O, Zn—O, Zn—O—Al, and Zn—Sn—O, electroconductive polymers such as polythiophene, polyaniline, polyacetylene, polyalkylthiophene derivatives, and polysilane derivatives doped with a metal, and α-Si and α-SiC can be cited.

The thickness of the transparent or semitransparent-first electrode layer is not particularly limited, and is properly set according to the transparent electroconductive material used. Specifically, the thickness of the transparent or semitransparent-first electrode layer is preferably in a range of 5 nm to 1000 nm, more preferably in a range of 40 nm to 500 nm. This is because, when the thickness of the transparent or semitransparent-first electrode layer is too small, the resistance might become higher. On the other hand, when the thickness is too large, there is a possibility that for instance, the semitransparent-second electrode layer is disconnected by a step at an edge of the patterned transparent or semitransparent-first electrode layer, or that the transparent or semitransparent-first electrode layer and the semitransparent-second electrode layer are short-circuited.

As the formation method of the transparent or semitransparent-first electrode layer, the chemical vapor deposition method, the physical vapor phase growth method such as the vacuum deposition method, the sputtering method, and the ion plating method are recited, for instance.

### 6. Transparent Substrate

The transparent substrate of the present invention supports the transparent or semitransparent-first electrode layer, the organic EL layer, the semitransparent-second electrode layer, the transparent or semitransparent-optical path length adjusting layer and the reflecting layer.

As mentioned above, since the organic EL element according to the present invention is of the bottom emission type in which light is taken out from the side of the transparent substrate, the transparent substrate needs to have transparency.

As the material for forming the transparent substrate, inorganic materials such as quartz, glass, silicon wafer, and glass formed with TFTs (thin film transistors) can be recited, for example. In addition, as the material for forming the transparent substrate, polymeric materials such as polycarbonate (PC), polyethylene terephthalate (PET), polybutylene terephthalate (PBT), polyphenylene sulfide (PPS), polyimide (PI), polyamide-imide (PAI), polyethersulfone (PES), polyetherimide (PEI), and polyether ether ketone (PEEK) can be recited, for example.

Among them, quartz, glass, and silicon wafer, or polyimide (PI), polyamide-imide (PAI), polyether sulfone (PES), polyetherimide (PEI), and polyether ether ketone (PEEK) that are super-engineering plastics are preferred. The reason is that these materials have heat resistance against 200° C. or more, so that the temperature of the transparent substrate can be elevated in the production step. Especially, when an active drive display device using TFT is manufactured, the above-mentioned materials can be suitably used, since the temperature becomes high in the production step.

The thickness of the transparent substrate is properly selected, depending upon the material used and usage of the organic EL element. Specifically, the thickness of the transparent substrate is around 0.005 mm to 5 mm.

When the above-mentioned polymeric material is used for the transparent substrate, the organic EL layer may be deteriorated with a gas generated from this polymeric material. Thus, a gas barrier layer is preferably formed between the transparent substrate and the transparent or semitransparent-first electrode layer. As the material for forming the gas barrier layer, silicon oxide and silicon nitride can be recited as examples.

### 7. Others

In the present invention, as mentioned above, when the electroconductivity of the reflecting layer is higher than that of the semitransparent-second electrode layer, it is preferable that the contact area in which the reflecting layer and the semitransparent-second electrode layer contact with each other is provided in the non-display area. The contact area may be simply provided inside the non-display area, but the size of the contact area is not particularly limited.

Further, the reflecting layer and the semitransparent-second electrode layer simply contact each other in the non-display area. As shown by an example in FIG. 4, it may be that the semitransparent-second electrode layer 7 contacts a take-out electrode 10, whereas the reflecting layer 9 does not contact the take-out layer 10. As shown by an example in FIG. 5, it may be that the reflecting layer 9 contacts the take-out electrode 10, whereas the semitransparent-second electrode layer 7 does not contact the take-out layer 10. Although not shown, both the semitransparent-second electrode layer and the reflecting layer may contact the take-out electrode.

For example, in the organic EL element 1 shown in FIG. 4, when the take-out electrode 10 is made of an electroconductive inorganic oxide such as ITO, a metal contained in the semitransparent-second electrode layer 7 may be oxidized by a reaction with oxygen contained in the take-out electrode 10. In this case, it may be hard for the take-out electrode and the semitransparent-second electrode layer to be conductive to each other. However, when the reflecting layer contacts the take-out electrode, current flows through the reflecting layer from the take-out electrode, and further flows from the reflecting layer to the semitransparent-second electrode layer in the contact area. Therefore, it is considered that even if it is hard for the take-out electrode and the semitransparent-second electrode layer to be conductive to each other, charges can be stably supplied to the light emitting layer.

The organic EL element according to the present invention may be an organic EL element of a laminated type called a multi photon emission type. That is, in the present invention, plural organic EL layers may be provided between the transparent or semitransparent-first electrode layer and the semitransparent-second electrode layer. In this case, an interlayer is formed between each organic EL layer.

With respect to the interlayer, see JP-A Nos. 11-329748, 2003-45676, 2003-272860, 2004-39617, and 2005-135600 for instance.

As applications of the organic EL element according to the present invention, advertisements, illuminations, displaying portions of displays, and back lights for displays can be recited, for example.

### B. Functional Device

The application scope of the present invention is not limited to the organic EL elements mentioned above. The semitransparent-second electrode layer, the transparent or semitransparent-optical path length adjusting layer and the reflecting layer in the present invention can be widely applied to functional devices in which the injecting function and the transporting function of the carriers (holes and electrons) are required, optical interference is used, and the oxidation of the metals contained in semitransparent-second electrode layer are desired to be prevented.

A functional device according to the present invention is characterized by comprising: a transparent substrate, a transparent or semitransparent-first electrode layer formed on the transparent substrate, a functional layer formed on the transparent or semitransparent-first electrode layer and adapted to exhibit its function with an electric field or current, a semitransparent-second electrode layer formed on the functional layer, a transparent or semitransparent-optical path length adjusting layer formed on the above semitransparent-second electrode layer and made of an inorganic material, and a reflecting layer formed on the transparent or semitransparent-optical path length adjusting layer.

As the functional device of the present invention, an inorganic EL element, an organic thin film solar cell can be recited as examples besides the organic EL element.

The functional layer used in the present invention is not particularly limited, so long as it exhibits its function by the electric field or current. The functional layer is properly selected according to the kind of the functional device. Specifically, as the functional layer, the inorganic EL layer, the solar cell layer, the transistor layer, and the memory layer can be recited as examples besides the organic EL layer.

The present invention is not limited to the above-mentioned embodiments. The embodiments are merely examples, and any one having the substantially same configuration as the technological idea disclosed in the claims of the present invention and the same effects is included in the technological scope of the present invention.

### EXAMPLES

Hereinafter, the present invention will be described concretely by using Examples and Comparative Examples.

### Example 1

First, a thin film of indium tin oxide (ITO) (thickness: 150 nm) was formed on a glass substrate by the sputtering method, and an anode (transparent or semitransparent-first electrode layer) was formed. The resulting substrate with the anode formed was washed, and treated with UV rays and ozone. Afterwards, a solution of polyethylene dioxythiophene-polyestylene sulfonate (abbreviated as “PEDOT-PSS”) was applied on the ITO thin film by the spin coating method in the atmosphere, and a hole injecting and transporting layer (thickness: 80 nm) was formed by drying after the application. Next, a solution of a fluorene based copolymer (manufactured by American Dye Source Inc., Product No. ADS133YE) was applied on the above hole injecting and transporting layer by the spin coating method in a glove box with thin oxygen (oxygen concentration: not more than 0.1 ppm) and low humidity (water vapor concentration: not more than 0.1 ppm), and a light emitting layer (thickness: 80 nm) was formed by drying after the application.

With respect to the substrate formed with the light emitting layer in the above, a Ca thin film (thickness: 20 nm) was formed on the light emitting layer in vacuum (pressure: 5×10⁻⁵ Pa) by the resistance heating deposition, thereby forming a semitransparent-second electrode layer (cathode).

Next, a film of ZnS is formed on the semitransparent-second electrode layer in vacuum (pressure: 5×10⁻⁵ Pa as a transparent or semitransparent-optical path length adjusting layer (thickness: 200 nm) by a resistance heating vapor deposition method.

At that time, the thickness of the transparent or semitransparent-optical path length adjusting layer was obtained by the following formula (1).

nd=λ×m/4 (1)

(herein, “n” is the refractive index of the transparent or semitransparent-optical path length adjusting layer, “d” is the film thickness of the transparent or semitransparent-optical path length adjusting layer, “λ” is the wavelength of the light to be weakened, and “m” is an arbitrary odd number.)

The refractive index “n” of ZnS is about 2.35. Thus, in order that the red light having a wavelength of λ=630 nm may be weakened to raise the chromatic purity of the green light, the thickness “d” of the transparent or semitransparent-optical path length adjusting layer is:

2.35×d=630×2/4

∴d=201 (nm)

Further, a thin film of Ag (thickness: 150 nm) was formed on the transparent or semitransparent-optical path length adjusting layer by the resistance heating vapor deposition method and a reflecting layer was formed.

After the formation of the reflecting layer, an organic EL element was obtained by sealing the resultant with non-alkaline glass in the glove box having thin oxygen (oxygen concentration: not more than 0.1 ppm) and low humidity (water vapor concentration: not more than 0.1 ppm).

While voltage was applied between the anode and the cathode of the organic EL element obtained, a radiated spectrum (emission spectrum) of the light emitted in the perpendicular direction to the flat plane of the substrate was measured. The measurement revealed that the chromaticity was (x, y)=(0.35, 0.61). Further, the emission spectrum had a peak wavelength of 530 nm, and the half-value width of the spectrum (the width of the spectrum at an intensity of 50% at the peak wavelength) was 35 nm.

Further, defects such as dark spots were not produced in an area where the organic EL element was observed with unassisted eyes.

### Comparative Example 1

An organic EL element was produced in the same manner as in Example 1 except that no transparent or semitransparent-optical path length adjusting layer was formed and a thin film of Ag was directly formed on a semitransparent-second electrode layer.

While voltage was applied between the anode and the cathode of the organic EL element obtained, a radiated spectrum of the light emitted in the perpendicular direction to the flat plane of the substrate was measured. The measurement revealed that the chromaticity was (x, y)=(0.41, 0.57). Further, the emission spectrum had a peak wavelength of about 540 nm, and the half-value width of the spectrum was 75 nm.

From the results of Example 1 and Comparative Example 1, it was confirmed that the formation of the transparent or semitransparent-optical path length adjusting layer changed the chromaticity and decreased the half-value width of the spectrum.

### Reference Example 1

An organic EL element was produced in the same manner as in Example 1 except that a reflecting layer was formed on a non-display area only.

While voltage was applied between the anode and the cathode of the organic EL element obtained, a light emitted state was examined. This revealed that excellent light emission was obtained even several days later.

### Reference Example 2

An organic EL element was produced in the same manner as in Example 1 except that a transparent or semitransparent-optical path length adjusting layer was formed by using Alq₃ instead of ZnS and a reflecting layer was formed on a non-display area only.

While voltage was applied between the anode and the cathode of the organic EL element obtained, a light emitted state was examined. This revealed that no light emission was obtained one day later.

It was understood from Reference Examples 1 and 2 that when the organic material such as Alq₃ was used for the transparent or semitransparent-optical path length adjusting layer, the transparent or semitransparent-optical path length adjusting layer could not sufficiently prevent the oxidation of the semitransparent-second electrode layer, and thus no light emission was obtained owing to the oxidation degradation of the semitransparent-second electrode layer with the passage of time. On the other hand, it was understood that when the inorganic material such as ZnS was used for the transparent or semitransparent-optical path length adjusting layer, the oxidation of the semitransparent-second electrode layer could be prevented by the transparent or semitransparent-optical path length adjusting layer, so that good light emission lasted even after the passage of several days.

What is claimed is:

1. An organic electroluminescence element comprising:
a transparent substrate,
a transparent or semitransparent-first electrode layer formed on the transparent substrate,
an organic electroluminescence layer formed on the transparent or semitransparent-first electrode layer and containing at least a light emitting layer,
a semitransparent-second electrode layer formed on the organic electroluminescence layer,
a transparent or semitransparent-optical path length adjusting layer formed on the semitransparent-second electrode layer and made of an inorganic material, and
a reflecting layer formed on the transparent or semitransparent-optical path length adjusting layer.

2. The organic electroluminescence element set forth in claim 1, wherein the reflecting layer has electroconductivity, and a contact area where the semitransparent-second electrode layer contacts the reflecting layer is provided in a non-display area.

3. The organic electroluminescence element set forth in claim 1, wherein the transparent or semitransparent-optical path length adjusting layer has a function to prevent oxidation of the semitransparent-second electrode layer.

4. The organic electroluminescence element set forth in claim 2, wherein the transparent or semitransparent-optical path length adjusting layer has a function to prevent oxidation of the semitransparent-second electrode layer.

5. The organic electroluminescence element set forth in claim 1, wherein the reflecting layer is formed in pattern.

6. The organic electroluminescence element set forth in claim 1, wherein the reflecting layer has a function to prevent oxidation of the semitransparent-second electrode layer.

7. The organic electroluminescence element set forth in claim 1, wherein the semitransparent-second electrode layer contains at least either one of an alkali metal and an alkaline earth metal.

8. The organic electroluminescence element set forth in claim 1, wherein an optical path length “nd” of the transparent or semitransparent-optical path length adjusting layer meets the following formula (1):
nd=λ×m/4 (1)
(herein, “n” is a refractive index of the transparent or semitransparent-optical path length adjusting layer, “d” is a film thickness of the transparent or semitransparent-optical path length adjusting layer, “λ” is a wavelength of a light to be weakened, and “m” is an arbitrary odd number.)

9. The organic electroluminescence element set forth in claim 1, wherein the inorganic material is a wide band gap semiconductor, a metal oxide, a metal sulfide or a metal fluoride.
